(19) United States
(12) Patent Application Publication
(10) Pub. No.: US 2021/0363384 A1
(43) Pub. Date: Nov. 25, 2021

(54) LIQUID CRYSTAL POLYMER COMPOSITION, COPPER SUBSTRATE, AND METHOD FOR MANUFACTURING THE COPPER SUBSTRATE

(71) Applicant: Zhen Ding Technology Co., Ltd., Tayuan (TW)

(72) Inventors: KUAN-WEI LEE, Tayuan (TW); SZU-HSIANG SU, Taoyuan (TW); SHOU-JUI HSIANG, Tayuan (TW); PEI-JUNG WU, Taoyuan (TW); WEI-HSIN HUANG, Tayuan (TW)

(21) Appl. No.: 16/906,471

(22) Filed: Jun. 19, 2020

(30) Foreign Application Priority Data
May 22, 2020 (CN) 202010443765.8

(51) Int. Cl. C09D 177/12; C09D 167/02; C09D 7/20; C09D 5/00; B05D 3/02

(52) U.S. Cl. CPC C09D 177/12; C09D 167/02; B05D 3/0254; C09D 5/00; C09D 7/20

(57) ABSTRACT

A liquid crystal polymer composition for a copper substrate with low dielectric constant and low dielectric loss suitable for use in printed circuit boards includes a solvent, a soluble liquid crystal polymer dissolved in the solvent, and a liquid crystal polymer powder dispersed in the solvent. The soluble LCP and the LCP powder form a solid content in the LCP composition. A mass ratio of the soluble LCP in the solid content of the LCP composition is in a range from 40% to 60%, and a mass ratio of the LCP powder in the solid content of the LCP composition is in a range from 40% to 60%.

### FIELD

The disclosure relates to printed circuit boards, and more particularly, to a liquid crystal polymer (LCP), a copper substrate including the LCP, and a method for manufacturing the copper substrate.

### BACKGROUND

Printed circuit boards include dielectric films and conductive wiring layers disposed on the dielectric films. Signal loss in the printed circuit board includes conduction loss in the conductive wiring layer and dielectric loss in the dielectric film. The dielectric loss is related to a dielectric constant Dₖ and a dielectric loss D_{f} of the dielectric material. To reduce the signal loss, dielectric material with a low dielectric constant and a low dielectric loss is needed. In addition, a polarity of the dielectric material also affects a stability of electron transmission in the conductive wiring layer. When the polarity of the dielectric material is too strong, the electrons in the conductive wiring layer may be attracted by the dielectric film after the printed circuit board is polarized, thereby lowering the stability of electron transmission.

LCP has a low dielectric constant, and also a low dielectric loss that can be maintained at about 0.0002 at a frequency of 10 GHz. Furthermore, the polarity of the LCP is weak. Thus, the LCP is used to manufacture the dielectric film. However, the solid content and the viscosity of the LCP are low, thus when the LCP is applied to form the dielectric film, film-forming properties and thickness of the dielectric film are limited.

### BRIEF DESCRIPTION OF THE DRAWING

Many aspects of the disclosure can be better understood with reference to the following drawings. The components in the drawings are not necessarily drawn to scale, the emphasis instead being placed upon clearly illustrating the principles of the disclosure.

FIG. 1 is a flowchart of an embodiment of a method for manufacturing an LCP composition.

FIG. 2 is a sub-flowchart of the method of FIG. 1.

FIG. 3 is a flowchart of an embodiment of a method for manufacturing a copper substrate.

FIG. 4 is a cross-sectional view of a first copper foil according to the present disclosure.

FIG. 5 is a cross-sectional view showing an LCP composition coated on the first copper foil of FIG. 4.

FIG. 6 is a cross-sectional view of a dielectric film formed by heating the LCP composition of FIG. 5.

FIG. 7 is a cross-sectional view showing a second copper foil formed on the dielectric film of FIG. 6 to form a copper substrate.

### DETAILED DESCRIPTION

Implementations of the disclosure will now be described, by way of embodiments only, with reference to the drawings. It should be noted that the embodiments and the features of the present disclosure can be combined without conflict. Specific details are set forth in the following description to make the present disclosure to be fully understood. The embodiments are only portions of, but not all the embodiments of the present disclosure. Based on the embodiments of the present disclosure, other embodiments obtained by a person of ordinary skill in the art without creative efforts shall be within the scope of the present disclosure.

Unless defined otherwise, all technical and scientific terms used herein have the same meaning as commonly understood by one of ordinary skill in the art. The terms used herein in the specification of the present disclosure are only for describing the embodiments and are not intended to limit the present disclosure. The term “and/or” as used herein includes any combination of one or more related items.

In the embodiments of the present disclosure, for descriptive convenience but not in limitation of the present disclosure, the term “connection” used in the specification and claims of the present disclosure is not limited to a physical or mechanical connection, whether direct connection or indirect connection. The terms of “up”, “down”, “above”, “below”, “left”, “right”, etc., are only used to indicate the relative position relationship. When the absolute position of the described element changes, the relative position relationship correspondingly changes.

The present disclosure provides an LCP composition in one embodiment. The LCP composition includes a soluble LCP, an LCP powder, and a solvent. The soluble LCP and the LCP powder form a solid content in the LCP composition. A mass ratio of the soluble LCP in the solid content of the LCP composition is in a range from 40% to 60%, and a mass ratio of the LCP powder in the solid content of the LCP composition is in a range from 40% to 60%. A sum of the mass ratio of the soluble LCP and the mass ratio of the LCP powder in the solid content of the LCP composition is equal to 100%.

The soluble LCP is dissolved in the solvent and liquid crystals are then formed. The LCP powder is insoluble but dispersed in the solvent. The LCP powder itself has liquid crystals before being dispersed in the solvent, which increases the solid content and a colloidal viscosity (1500˜2000 cps), and also increases a colloidal stability of the LCP composition. Therefore, the film-forming properties of the LCP composition are improved. The thickness of the dielectric film can be controlled, so that it is not less than 25 μm when the LCP composition is coated in a single step.

Furthermore, the LCP powder has an ester functional group (—COO—). The soluble LCP has an amide functional group (—CONH₂) and an ester functional group, which bond two adjacent aromatic groups together. When the soluble LCP and the LCP powder are mixed and heated, the soluble LCP forms liquid crystals. The liquid crystals of the soluble LCP and the liquid crystals of the LCP powder are cross-linked together by the functional groups to form a network structure with improved mechanical properties. Therefore, when the LCP is used to manufacture a copper substrate, the copper substrate will have a high peel strength greater than 0.7 kgf/cm and a high heat resistance. Moreover, since the amount of the liquid crystals is increased, the electrical properties of the LCP composition are also improved (the dielectric constant Dₖ is in a range from 3.3 to 3.4, and the dielectric loss D_{f} is in a range from 0.001 to 0.002).

Therefore, the LCP composition can be used to manufacture a high-frequency circuit board with low signal loss.

When the mass ratio of the LCP powder in the solid content of the LCP composition is greater than 60%, the LCP powder may become stress concentration points in the LCP composition, which decreases the peel strength and the elongation percentage. When the mass ratio of the LCP powder in the solid content of the LCP composition is less than 40%, the amount of the LCP powder is insufficient to increase the solid content and the colloidal viscosity of the LCP composition, which results in poor film-forming properties. Furthermore, the electrical properties cannot meet a target value of (D_{f}≤0.002).

In at least one embodiment, the solid content of the LCP composition is in a range from 10% to 20%, and a mass ratio of the solvent in the LCP composition is in a range from 80% to 90%. When the solid content of the LCP composition is less than 10%, the LCP composition has a low viscosity, which results in relatively poor film-forming properties. When the solid content of the LCP composition is more than 20%, the soluble LCP cannot be completely dissolved in the solvent with an insufficient amount, the LCP powder is also not uniformly dispersed in the solvent, which results in uneven dispersion and precipitation. During heating, discontinuous pores and an uneven thickness occur, resulting in an unstable property of the dielectric film properties and a significant decrease in the mechanical properties. The solvent includes, but is not limited to, N-methylpyrrolidone (NMP).

In at least one embodiment, a particle size of the LCP powder is less than 3 μm. When the particle size of the LCP powder is greater than 3 μm, the LCP powder does not disperse in the solvent, which results in precipitation. During heating, discontinuous pores and an uneven thickness also occur.

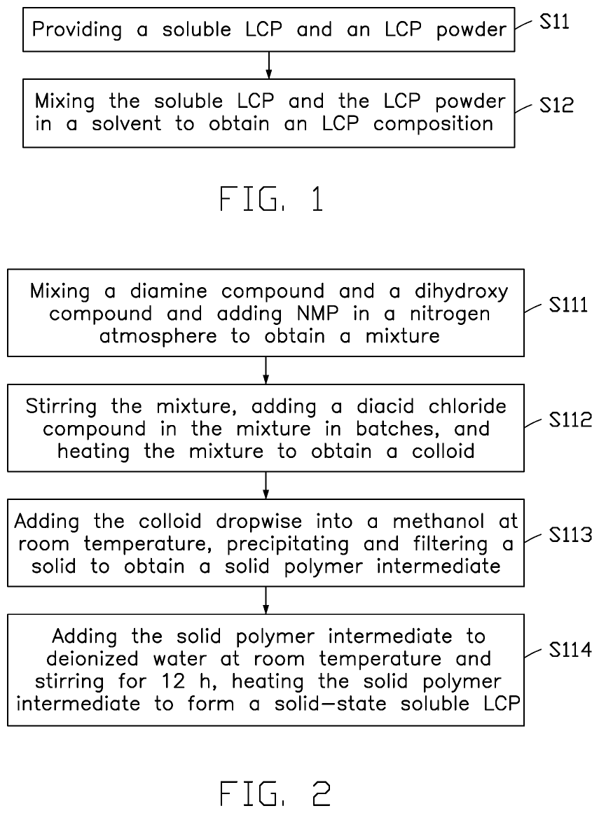

Referring to FIG. 1, the present disclosure further provides an embodiment of a method for manufacturing the LCP composition. The method is provided by way of example, as there are a variety of ways to carry out the method. The exemplary method can begin at step S11.

At step S11, the soluble LCP and the LCP powder are provided.

In at least one embodiment, also referring to FIG. 2, the soluble LCP is manufactured by an exemplary method beginning at step S111.

At step S111, a diamine compound and a dihydroxy compound are mixed, and the NMP is added in a nitrogen atmosphere to obtain a mixture.

In at least one embodiment, the diamine compound is m-phenylenediamine (MPDA), and the dihydroxy compound is at least one of 1,3-dihydroxybenzene and resorcinol.

At step S112, the mixture is stirred to dissolve the diamine compound and the dihydroxy compound in the NMP, and then a diacid chloride compound is added in the mixture in batches. A time interval between two adjacent batches is about 1 h. After all the diacid chloride compound has been added, the mixture is heated to 80 degrees Celsius and stirred for 24 h to undergo an esterification reaction. Thereby a colloid is obtained.

A ratio of a sum of a mole number of the diamine compound and a mole number of the dihydroxy compound set against a mole number of the diacid chloride compound is 1:1. In at least one embodiment, the diacid chloride compound is at least one of isophthaloyl chloride, terephthaloyl chloride, 4,4′-oxybis (benzoyl chloride), 4,4′-bisphenyldicarbonyl chloride, and bi (cyclohexane)-4,4′-dicarbonyl dichloride.

At step S113, the colloid is added dropwise into 500 mL of methanol at room temperature, and the solid is precipitated and filtered to obtain a solid polymer intermediate.

At step S114, the solid polymer intermediate is added to 500 mL of deionized water at room temperature and stirred for 12 h. The solid polymer intermediate is then filtered and washed three times to remove the byproduct HCl. The solid polymer intermediate is then heated in a vacuum environment at 60 degrees Celsius to form a solid-state soluble LCP.

In this embodiment, two adjacent aromatic groups of the soluble LCP are bonded together through the amide group and the ester group.

In another embodiment, the soluble LCP can also be manufactured by the dihydroxy compound and the diacid chloride compound. A ratio of the mole number of the dihydroxy compound set against the moles of the diacid chloride is 1:1. In this embodiment, the two adjacent aromatic groups of the soluble LCP are bonded together through the ester group.

In at least one embodiment, the LCP powder is manufactured by crushing a 2-axis stretched film.

At step S12, the soluble LCP and the LCP powder are mixed in a solvent to obtain the LCP composition.

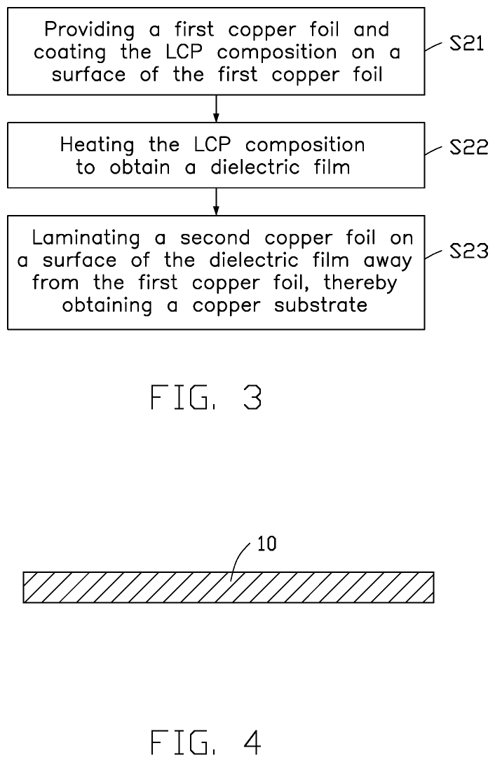

Referring to FIG. 3, the present disclosure further provides a method for preparing a copper substrate. The method is provided by way of example, as there are a variety of ways to carry out the method. The exemplary method can begin at step S21.

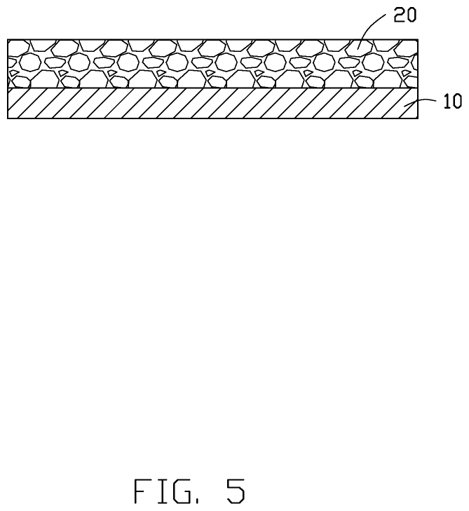

At step S21, referring to FIGS. 4 and 5, a first copper foil 10 is provided, and the LCP composition 20 is coated on a surface of the first copper foil 10.

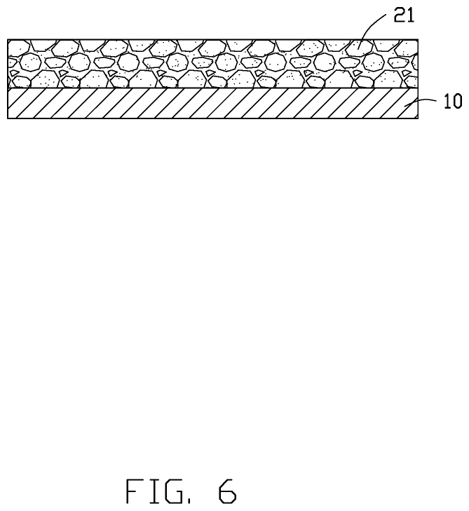

At step S22, referring to FIG. 6, the LCP composition 20 is heated to obtain a dielectric film 21.

In at least one embodiment, the LCP composition 20 is heated in a nitrogen atmosphere, at a temperature from 350 degrees Celsius to 370 degrees Celsius, for duration of 30 minutes to 60 minutes. The temperature can be adjusted according to a glass transition temperature of the LCP composition.

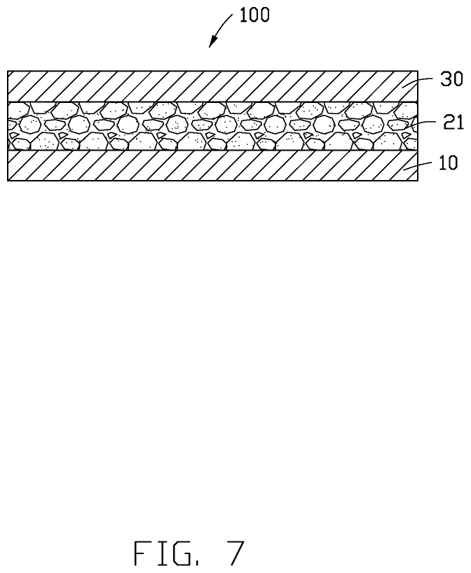

At step S23, referring to FIG. 7, a second copper foil 30 is laminated on a surface of the dielectric film 21 away from the first copper foil 10, thereby obtaining the copper substrate 100.

In at least one embodiment, the second copper foil 30 is laminated on the first copper foil 10 at a temperature of 350 degrees Celsius to 370 degrees Celsius.

### Synthesis Example 1

2.54 g of 1,5-pentanediol and 142.50 g of NMP were added in sequence into a 500 ml reaction bottle, and stirred for 30 min. Then, isophthaloyl chloride (total amount is 4.96 g) was added in five batches into the reaction bottle and stirred for 24 h. After solid precipitation, filtration, washing, and drying, a solid-state soluble polyester was obtained.

### Synthesis Example 2

1.30 g of m-phenylenediamine, 1.32 g of resorcinol, and 142.50 g of NMP were added in sequence into a 500 ml reaction bottle, and stirred for 30 min. Then, isophthaloyl chloride (total amount of addition is 4.88 g) was added in five batches into the reaction bottle and stirred for 24 h. After solid precipitation, filtration, washing, and drying, the solid-state soluble LCP was obtained.

Conditions for manufacturing the soluble LCP of Synthesis Examples 1 and 2 are recorded in Table 1 following.

TABLE 1

| | | Synthesis | Synthesis |
|---|---|---|---|
| | | Exa. 1 | Exa. 2 |
| Ratio of | Isophthaloyl chloride | 50 | 50 |
| mole | 1,5-pentanediol | 50 | / |
| number | M-phenylenediamine | / | 25 |
| (%) | Resorcinol | / | 25 |

### Example 1

4 g of aromatic liquid crystal polyester (LF31-P) with a particle size less than 3 μm, 6 g of soluble LCP prepared in Synthesis Example 2, and 54 g of NMP were added in sequence into a 100 ml reaction bottle and stirred for 2 h to obtain the LCP composition.

### Example 2

4 g of LF31-P with a particle size less than 3 μm and 75 g of commercially available VR300 (solid content 8%) were added in sequence into a 100 ml reaction bottle and stirred for 2 h to obtain the LCP composition.

### Example 3

6 g of LF31-P with a particle size less than 3 μm, 4 g of soluble LCP prepared in Synthesis Example 2, and 76 g of NMP were added in sequence into a 100 ml reaction bottle and stirred for 2 h to obtain the LCP composition.

### Example 4

6 g of LF31-P with a particle size less than 3 μm, 50 g of commercially available VR300 (solid content 8%), and 23.0 g of NMP were added in sequence into a 100 ml reaction bottle and stirred for 2 h to obtain the LCP composition.

### Comparative Example 1

5 g of fluorine-based powder (PTFE, particle size less than 3 μm), 0.6 g of polyether polyamide (surfactant), and 44.6 g of NMP were added in sequence into a 100 ml reaction bottle and stirred for 2 h to obtain a PTFE dispersion liquid.

### Comparative Example 2

3.5 g of LF31-P (particle size less than 3 μm) and 31.5 g of NMP were added in sequence into a 100 ml reaction bottle and stirred for 2 h to obtain an LCP dispersion liquid.

### Comparative Example 3

5 g of PTFE (particle size less than 3 μm), 0.6 g of polyether polyamide, 5 g of soluble polyester prepared in Synthesis Example 1, and 45 g of NMP were added in sequence into a 100 ml reaction bottle, and stirred for 2 h to obtain a PTFE dispersion liquid.

### Comparative Example 4

5 g of PTFE (particle size less than 3 μm), 0.6 g of polyether polyamide, 5 g of soluble LCP prepared in Synthesis Example 2, and 45 g of NMP were added in sequence into a 100 ml reaction bottle, and stirred for 2 h to obtain a PTFE dispersion liquid.

### Comparative Example 5

5 g of PTFE (particle size less than 3 μm), 0.6 g of polyether polyamide, and 62.5 g of commercially available VR300 (solid content 8%), were added in sequence into a 100 ml reaction bottle, and stirred for 2 h to obtain a PTFE dispersion liquid.

### Comparative Example 6

3.5 g of LF31-P (particle size less than 3 μm), 6.5 g of soluble polyester prepared in Synthesis Example 1, and 58.5 g of NMP were added in sequence into a 100 ml reaction bottle and stirred for 2 h to obtain an LCP dispersion liquid.

### Comparative Example 7

3.5 g of LF31-P (particle size less than 3 μm), 6.5 g of soluble LCP prepared in Synthesis Example 2, and 58.5 g of NMP were added in sequence into a 100 ml reaction bottle and stirred for 2 h to obtain an LCP dispersion liquid.

### Comparative Example 8

3.5 g of LF31-P (particle size less than 3 μm) and 81.25 g of commercially available VR300 (solid content 8%) were added in sequence into a 100 ml reaction bottle and stirred for 2 h to obtain an LCP dispersion liquid.

### Comparative Example 9

6.5 g of LF31-P (particle size less than 3 μm), 3.5 g of soluble LCP prepared in Synthesis Example 2, and 66.5 g of NMP were added in sequence into a 100 ml reaction bottle and stirred for 2 h to obtain an LCP dispersion liquid.

### Comparative Example 10

6.5 g of LF31-P (particle size less than 3 μm), 43.75 g of commercially available VR300 (solid content 8%), and 26.3 g of NMP were added in sequence into a 100 ml reaction bottle and stirred for 2 h to obtain an LCP dispersion liquid.

The LCP compositions prepared in Examples 1-4 and the dispersion liquids prepared in Comparative Examples 1-10 were subjected to a viscosity test. Then each of the LCP compositions prepared in Examples 1-4 and the dispersion liquids prepared in Comparative Examples 1-10 were used to prepare a copper substrate, including steps of: (1) coating the LCP composition or the dispersion liquid on a commercially available electrolytic copper film with a thickness of 12 μm, and the composition or the dispersion liquid was coated with a thickness greater than or equal to 25 μm; (2) heating the LCP composition or the dispersion liquid in a nitrogen atmosphere, at a temperature of 350 degrees Celsius to 370 degrees Celsius for 30 to 60 minutes, thereby obtaining a single-sided copper substrate; (3) laminating another commercially available electrolytic copper film with a thickness of 12 μm on the dielectric film at a temperature of 350 degrees Celsius to 370 degrees Celsius, thereby obtaining a double-sided copper substrate.

The mechanical properties and electrical properties of each copper substrate were tested, and the test results are recorded in Tables 2 and 3 following.

TABLE 2

| | | | Exa. 1 | Exa. 2 | Exa. 3 | Exa. 4 |
|---|---|---|---|---|---|---|
| Solid | LCP | LF31-P | 40 | 40 | 60 | 60 |
| content | powder | | | | | |
| (%) | Soluble | Synthesis | 60 | / | 40 | / |
| | LCP | Exa. 2 | | | | |
| | | VR300 | / | 60 | / | 40 |

| | | | | |
|---|---|---|---|---|
| NMP (g) | 54 | / | 76 | 23 |
| Viscosity (cps) | 1530 | 1810 | 1750 | 1935 |
| Peel strength (kgf/cm) | 0.75 | 0.73 | 0.76 | 0.71 |
| Tensile strength (MPa) | 142 | 152 | 140 | 153 |
| Elongation percentage (%) | 21.2 | 28.2 | 23.1 | 34.2 |
| Film-forming properties | Coat in | Coat in | Coat in | Coat in |
| (thickness25 μm, | a single | a single | a single | a single |
| without pores) | step | step | step | step |
| Solder Float Test | PASS | PASS | PASS | PASS |
| (288□/10 sec) | | | | |
| Dₖ (10 GHz) | 3.4 | 3.3 | 3.4 | 3.4 |
| D_{f} (10 GHz) | 0.002 | 0.002 | 0.001 | 0.001 |

TABLE 3

| | | | Comparative | Comparative | Comparative | Comparative | Comparative | Comparative |
|---|---|---|---|---|---|---|---|---|
| | | | Exa. 1 | Exa. 2 | Exa. 3 | Exa. 4 | Exa. 5 | Exa. 6 |
| Solid | LCP | PTFE | 100 | / | 50 | 50 | 50 | / |
| content | powder | LF31-P | | 100 | / | / | / | 35 |
| (%) | Soluble | Synthesis | / | / | 50 | / | / | 65 |
| | LCP | Exa. 1 | | | | | | |
| | | Synthesis | / | / | / | 50 | / | / |
| | | Exa. 2 | | | | | | |
| | | VR300 | / | / | / | / | 50 | / |

| | | | | | | |
|---|---|---|---|---|---|---|
| NMP (g) | 44.6 | 31.5 | 45 | 45 | 0 | 58.5 |
| Viscosity (cps) | 130 | 3350 | Phase | Phase | Phase | 982 |
| | | | separation | separation | separation | |
| Peel strength (kgf/cm) | 0.3 | / | / | / | / | 0.11 |
| Tensile strength (MPa) | 30 | / | / | / | / | 32 |
| Elongation percentage (%) | 60 | / | / | / | / | 8.2 |
| Film-forming properties | Coat in | Film | / | / | / | Coat in |
| (thickness25 μm, | two steps | cannot be | | | | two steps |
| without pores) | | formed | | | | |
| Solder Float Test | PASS | / | / | / | / | PASS |
| (288□/10 sec) | | | | | | |
| Dₖ (10 GHz) | 2.3 | 3.5 | / | / | / | 3.4 |
| D_{f} (10 GHz) | 0.001 | 0.0007 | / | / | / | 0.01 |

| | | | Comparative | Comparative | Comparative | Comparative |
|---|---|---|---|---|---|---|
| | | | Exa. 7 | Exa. 8 | Exa. 9 | Exa. 10 |
| Solid | LCP | PTFE | / | / | / | / |
| content | powder | LF31-P | 35 | 35 | 65 | 65 |
| (%) | Soluble | Synthesis | | / | / | / |
| | LCP | Exa. 1 | | | | |
| | | Synthesis | 65 | / | 35 | |
| | | Exa. 2 | | | | |
| | | VR300 | / | 65 | / | 35 |

| | | | | |
|---|---|---|---|---|
| NMP (g) | 58.5 | 0 | 66.5 | 26.3 |
| Viscosity (cps) | 1130 | 1290 | 2550 | 2545 |
| Peel strength (kgf/cm) | 0.72 | 0.75 | 0.53 | 0.49 |
| Tensile strength (MPa) | 142 | 152 | 41 | 38 |
| Elongation percentage (%) | 15.7 | 26.8 | 6.2 | 4.2 |
| Film-forming properties | Coat in | Coat in | Coat in | Coat in |
| (thickness25 μm, | two steps | two steps | a single | a single |
| without pores) | | | step | step |
| Solder Float Test | PASS | PASS | PASS | PASS |
| (288□/10 sec) | | | | |
| Dₖ (10 GHz) | 3.4 | 3.3 | 3.4 | 3.4 |
| D_{f} (10 GHz) | 0.003 | 0.003 | 0.001 | 0.001 |

Referring to Tables 2 and 3, in Comparative Examples 1, 3-5, although the fluorine-based powder (PTFE) also has crystalline polymer and good electrical properties and elongation percentage, the dispersion liquids made of the fluorine-based powder and the soluble CLP have poor film-forming properties. In particular, phase separation occurs in the dispersion liquids in Comparative Examples 3-5, which prevents the dispersion liquids being used to manufacture the dielectric film. In Comparative Example 2, only LCP powder is added to the dispersion liquid, and no soluble LCP is added. That is, the liquid crystals of the LCP powder cannot be cross-linked with the liquid crystals of the soluble LCP. Thus, the dispersion liquid in Comparative Example 2 cannot form a film.

However, the LCP compositions of Examples 1-4 have both the soluble LCP and the LCP powder, and thus have higher viscosity and better film-forming properties. A dielectric film with a thickness of 25 μm can be obtained when the LCP composition is coated in a single step. Moreover, the copper substrates of Examples 1-4 have a low dielectric constant, a low dielectric loss, and a high peel strength.

In addition, the soluble LCP and the LCP powder are both added in Comparative Examples 6-10. However, the LCP composition in Comparative Examples 6-8 has a poor film-forming property, and the electrical property does not meet the target value of (D_{f}≤0.002) since there is a relatively low mass ratio of the LCP powder and a low viscosity of the LCP composition. The D_{f} value of Comparative Example 6 is much higher than the target value, this is because the 1,5-pentanediol used in Synthesis Example 1 is a diphenol tertiary monomer with a long carbon chain, which prevents the soluble polyester in Synthesis Example 1 from having liquid crystals. Thus, the soluble polyester in Synthesis Example 1 has poor electrical property and also lacks liquid crystals to form a cross-linked network with the LCP powder during the heating process. On the contrary, the mechanical properties are reduced. Thus, the LCP powder is not suitable for mixing with the soluble polyester if there are no liquid crystals. In Comparative Examples 9-10, the mass ratio of the LCP powder is too high, which leads to stress concentration points and results in a decrease in mechanical properties such as peel strength and elongation percentage.

Although the embodiments of the present disclosure have been shown and described, those having ordinary skill in the art can understand that changes may be made within the principles of the present disclosure, up to and including the full extent established by the broad general meaning of the terms used in the claims. It will, therefore, be appreciated that the embodiments described above may be modified within the scope of the claims.

What is claimed is:

1. A liquid crystal polymer (LCP) composition, comprising:
a solvent;
a soluble liquid crystal polymer dissolved in the solvent; and
a liquid crystal polymer powder dispersed in the solvent;
wherein the soluble LCP and the LCP powder form a solid content in the LCP composition, a mass ratio of the soluble LCP in the solid content of the LCP composition is in a range from 40% to 60%, and a mass ratio of the LCP powder in the solid content of the LCP composition is in a range from 40% to 60%.

2. The liquid crystal polymer composition of claim 1, wherein the solid content of the liquid crystal polymer composition is in a range from 10% to 20%, and a mass ratio of the solvent in the LCP composition is in a range from 80% to 90%.

3. The liquid crystal polymer composition of claim 1, wherein the solvent comprises N-methylpyrrolidone.

4. The liquid crystal polymer composition of claim 1, wherein a particle size of the liquid crystal polymer powder is less than 3 μm.

5. A method for manufacturing a copper substrate, comprising:
providing a liquid crystal polymer composition comprising a solvent, a soluble liquid crystal polymer dissolved in the solvent, and a liquid crystal polymer powder dispersed in the solvent, wherein the soluble LCP and the LCP powder form a solid content in the LCP composition, a mass ratio of the soluble LCP in the solid content of the LCP composition is in a range from 40% to 60%, and a mass ratio of the LCP powder in the solid content of the LCP composition is in a range from 40% to 60%;
coating the liquid crystal polymer composition on a surface of a first copper foil; and
heating the liquid crystal polymer composition to obtain a dielectric film.

6. The method of claim 5, further comprising:
laminating a second copper foil pressed on a surface of the dielectric film away from the first copper foil, at a temperature from 350 degrees Celsius to 370 degrees Celsius.

7. The method of claim 5, wherein the liquid crystal polymer composition is heated in a nitrogen atmosphere, at a temperature from 350 degrees Celsius to 370 degrees Celsius, for duration of 30 minutes to 60 minutes.

8. The method of claim 5, wherein the solid content of the liquid crystal polymer composition is in a range from 10% to 20%, and a mass ratio of the solvent in the LCP composition is in a range from 80% to 90%.

9. The method of claim 5, wherein the solvent comprises N-methylpyrrolidone.

10. The method of claim 5, wherein a particle size of the liquid crystal polymer powder is less than 3 μm.

11. A copper substrate, comprising:
a first copper foil; and
a dielectric film disposed on a surface of the first copper foil;
wherein the dielectric film comprises a soluble liquid crystal polymer and a liquid crystal polymer powder, a mass ratio of the soluble LCP in the solid content of the LCP composition is in a range from 40% to 60%, and a mass ratio of the LCP powder in the solid content of the LCP composition is in a range from 40% to 60%, the soluble liquid crystal polymer and the liquid crystal polymer powder are cross-linked with each other and form a network structure.

12. The copper substrate of claim 11, wherein a particle size of the liquid crystal polymer powder is less than 3 μm.
